(19) United States
(12) Patent Application Publication
(10) Pub. No.: US 2020/0196489 A1
(43) Pub. Date: Jun. 18, 2020

(54) HEAT DISSIPATION APPARATUS AND SERVER USING THE SAME

(71) Applicant: HONGFUJIN PRECISION ELECTRONICS (TIANJIN) CO.,LTD., Tianjin (CN)

(72) Inventors: CHIH-HUNG CHANG, New Taipei (TW); CHAO-KE WEI, New Taipei (TW); TZE-CHERN MAO, New Taipei (TW); YEN-CHUN FU, New Taipei (TW); YAO-TING CHANG, New Taipei (TW); LI-WEN CHANG, New Taipei (TW)

(21) Appl. No.: 16/234,425

(22) Filed: Dec. 27, 2018

(30) Foreign Application Priority Data
Dec. 15, 2018 (CN) 201811537274.9

(51) Int. Cl. H05K 7/20

(52) U.S. Cl. CPC H05K 7/20772; H05K 7/20272; H05K 7/20236

(57) ABSTRACT

A heat dissipation apparatus for a plurality of heat-generating electrical devices in a server dissipates heat of the heat-generating electrical devices by using heat-absorbing liquid. The apparatus includes a container, an inlet pipe, and an outlet pipe. The container contains a non-conductive coolant liquid and the plurality of heat-generating electrical devices are entirely submerged in the coolant liquid.

### FIELD

The subject matter herein generally relates heat dissipation apparatus.

### BACKGROUND

Computer data centers are proliferating. During operation of such data centers, server systems generate a lot of heat. Traditional cooling by air flow requires a lot of space.

Therefore there is a room for improvement.

### BRIEF DESCRIPTION OF THE DRAWINGS

Implementations of the present disclosure will now be described, by way of example only, with reference to the attached figures.

FIG. 1 is a schematic diagram of an exemplary embodiment of a server of the disclosure, wherein the server includes a heat-generating electrical device.

FIG. 2 is another schematic diagram of an exemplary embodiment of the server of the disclosure.

FIG. 3 a schematic diagram of the heat-generating electrical device of the server of FIG. 1.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series, and the like.

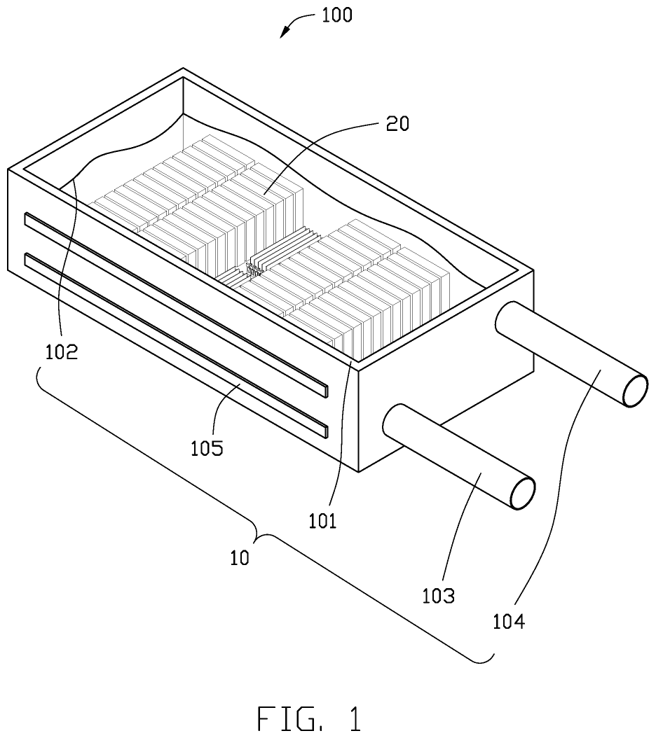

FIG. 1 illustrates a server 100 in accordance with an exemplary embodiment of the present disclosure. The server 100 includes a heat dissipation apparatus 10 and a plurality of heat-generating electrical devices 20.

The heat dissipation apparatus 10 dissipates heat of the plurality of heat-generating electrical devices 20.

In at least one exemplary embodiment, the heat dissipation apparatus 10 includes a container 101. The container 101 contains coolant liquid 102 and the plurality of heat-generating electrical devices 20. The plurality of heat-generating electrical devices 20 can be installed inside of the container 101 and can be submerged in the coolant liquid 12.

The heat dissipation apparatus 10 further includes an inlet pipe 103 and an outlet pipe 104.

Both the inlet pipe 103 and the outlet pipe 104 can be connected to the container 101.

In at least one exemplary embodiment, the coolant liquid 12 enters the container 101 through the inlet pipe 103, and the coolant liquid 12 flows out from the container 101 through the outlet pipe 104.

In this manner, the coolant liquid 102 cyclically dissipates heat from the plurality of heat-generating electrical devices 20 of the server 100.

In at least one exemplary embodiment, the coolant liquid 102 can be non-conductive, the plurality of heat-generating electrical devices 20 thus will not be short-circuited when submerged in the coolant liquid 102.

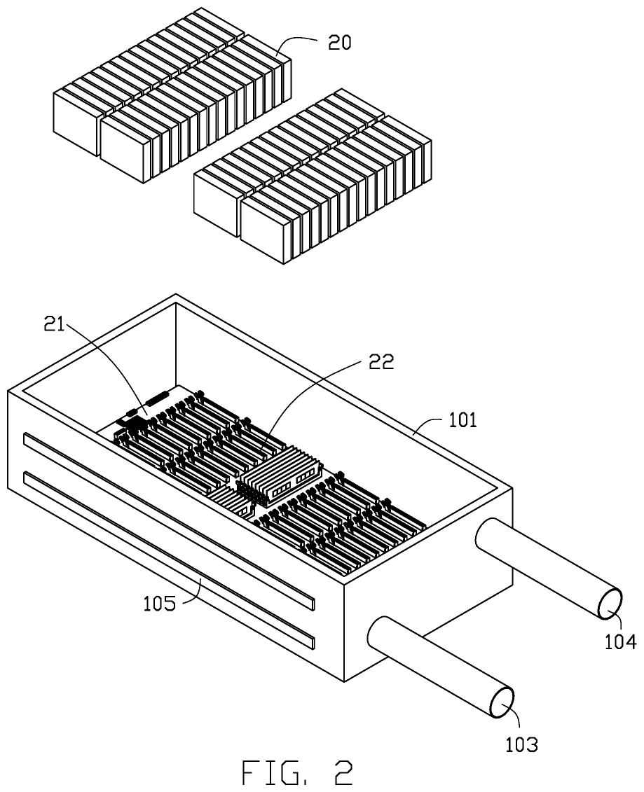

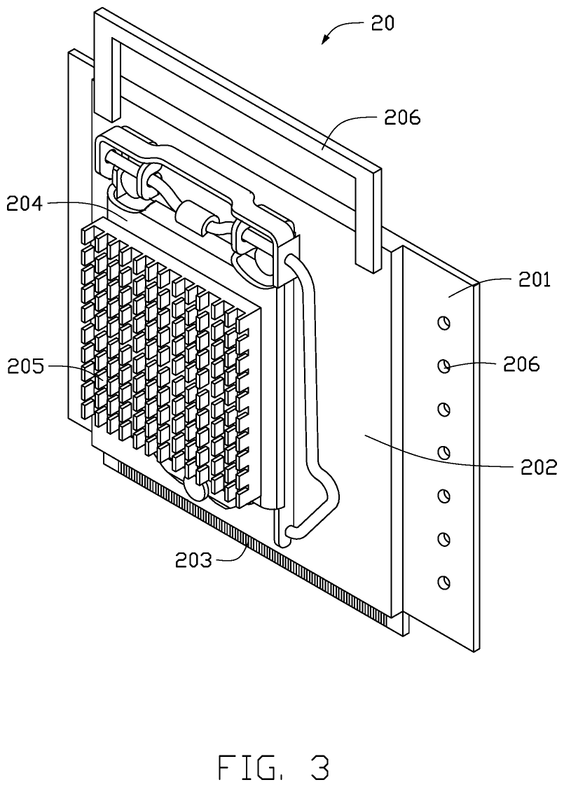

FIG. 2 and FIG. 3 illustrate a plurality of slide rails 105 being disposed on both sides of the container 101.

In at least one exemplary embodiment, the plurality of slide rails 105 can be installed in a standard cabinet (not shown).

In at least one exemplary embodiment, the server 100 further includes a motherboard 21.

The motherboard 21 can be installed inside of the container 101 and be also submerged by the coolant liquid 12.

The motherboard 21 can include a plurality of slots 22. Each heat-generating electrical device 20 matches a slot 22.

The plurality of heat-generating electrical devices 20 can be plugged into the motherboard 21. Therefore, the motherboard 21 and the plurality of heat-generating electrical devices 20 are together submerged in the coolant liquid 12.

When the motherboard 21 and the plurality of heat-generating electrical devices 20 are powered on, the plurality of heat-generating electrical devices 20 emit heat (such as a central processing unit of the motherboard during booting). The coolant liquid 12 can dissipate heat of the plurality of heat-generating electrical devices 20 and the motherboard 21.

In at least one exemplary embodiment, the heat-generating electrical device 20 includes a housing 201 and a printed circuit board (PCB) 202. The PCB 202 is fixedly connected to the inside of the housing 201.

In at least one exemplary embodiment, the heat-generating electrical device 20 further includes a plurality of edge connectors (gold fingers 203). The heat-generating electrical device 20 can be inserted into the slot 22 of the motherboard 21 through the plurality of gold fingers 203.

The heat-generating electrical device 20 further includes a processing chip 204. The processing chip 204 is fixedly connected to the printed circuit board 202.

In at least one exemplary embodiment, the heat-generating electrical device 20 further includes a heat exchanger 205. The heat exchanger 205 contacts the processing chip 204, and dissipates heat of the processing chip 204.

The heat-generating electrical device 20 can further include a handheld portion 206. The handhold portion 205 is fixedly connected to the housing 201. The heat-generating electrical device 20 can be easily inserted and removed from the motherboard 21 by using the handheld portion 206.

In at least one exemplary embodiment, the surface of the housing 201 can also include a mesh (not shown).

The mesh increases the contact area between the coolant liquid 102 and the housing 201 of the heat-generating electrical device 20.

In at least one exemplary embodiment, the processing chip 204 can be a central processing unit (CPU). In other exemplary embodiment, the processing chip 204 can be a graphics processing unit (GPU) or other high power chip.

The cooling liquid 102 is circulated among the plurality of heat-generating electrical devices 20. The server 100 is able to meet heavy demands regarding heat dissipation.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the exemplary embodiments described above may be modified within the scope of the claims.

1-3. (canceled)

4. A server, comprising:
a plurality of heat-generating electrical devices; and
a heat dissipation apparatus comprising:
a container containing coolant liquid and the plurality of heat-generating electrical devices, wherein the plurality of heat-generating electrical devices is submerged by the coolant liquid;
an inlet pipe connecting to the container, wherein the coolant liquid enters the container through the inlet pipe; and
an outlet pipe connecting to the container, wherein the coolant liquid flows out from the container through the outlet pipe;
wherein the heat-generating electrical device comprises a housing, a surface of the housing defines a plurality of meshes, the plurality of the meshes increases the contact area between the coolant liquid and the housing of the heat-generating electrical device;
wherein the server comprises a motherboard, and the motherboard is installed inside of the container and submerged by the coolant liquid; and wherein the motherboard comprises a plurality of slots, and each heat-generating electrical device is correspondingly matched with each slot of the motherboard; wherein the heat-generating electrical device further comprises a printed circuit board (PCB), and the printed circuit board is fixedly connected to the inside of the housing;
wherein the heat-generating electrical device comprises a plurality of gold fingers, and the heat-generating electrical device is inserted into the slot of the motherboard through the plurality of gold fingers; wherein the heat-generating electrical device comprises a processing chip, and the processing chip is fixedly connected to the printed circuit board; wherein the heat-generating electrical device comprises a heat exchanger, and the heat exchanger contacts with the processing chip and dissipates heat of the processing chip; and
wherein the heat-generating electrical device comprises a handheld portion, and the handhold portion is fixedly connected to the housing.

5-13. (canceled)

14. The server of claim 4, wherein the processing chip is a central processing unit or a graphics processing unit.

15. A server, comprising:
a motherboard;
a plurality of heat-generating electrical devices; and
a heat dissipation apparatus comprising:
a container containing coolant liquid and the plurality of heat-generating electrical devices, wherein the plurality of heat-generating electrical devices is submerged by the coolant liquid;
an inlet pipe connecting to the container, wherein the coolant liquid enters the container through the inlet pipe; and
an outlet pipe connecting to the container, wherein the coolant liquid flows out from the container through the outlet pipe,
wherein the motherboard is installed inside of the container and submerged by the coolant liquid; and
wherein the heat-generating electrical device comprises a housing, a surface of the housing defines a plurality of meshes, the plurality of the meshes increases the contact area between the coolant liquid and the housing of the heat-generating electrical device;
wherein the coolant liquid is non-conductive insulation liquid; and wherein the container comprises a plurality of slide rails, the plurality of slide rails are disposed on both sides of the container, and the plurality of slide rails are installed in a cabinet; wherein the motherboard comprises a plurality of slots, and each heat-generating electrical device is correspondingly matched with each slot of the motherboard;
wherein the heat-generating electrical device further comprises a printed circuit board (PCB) and a plurality of gold fingers, the printed circuit board is fixedly connected to the inside of the housing, and the heat-generating electrical device is inserted into the slot of the motherboard through the plurality of gold fingers; wherein the heat-generating electrical device comprises a processing chip, and a heat exchanger; the processing chip is fixedly connected to the printed circuit board, and the heat exchanger contacts with the processing chip and dissipates heat of the processing chip;
wherein the heat-generating electrical device comprises a handheld portion, and the handhold portion is fixedly connected to the housing.

16-20. (canceled)
